(19) United States
(12) Patent Application Publication
(10) Pub. No.: US 2022/0091155 A1
(43) Pub. Date: Mar. 24, 2022

(54) SENSOR COMPONENT INCLUDING A MICROELECTROMECHANICAL Z INERTIAL SENSOR AND METHOD FOR ASCERTAINING AN ACCELERATION WITH THE AID OF THE MICROELECTROMECHANICAL Z INERTIAL SENSOR

(71) Applicant: Robert Bosch GmbH, Stuttgart (DE)

(72) Inventor: Martin Rambach, Pliezhausen (DE)

(21) Appl. No.: 17/448,246

(22) Filed: Sep. 21, 2021

(30) Foreign Application Priority Data
Sep. 23, 2020 (DE) 102020211924.4

(51) Int. Cl. G01P 15/125; G01P 15/08; B81B 7/00

(52) U.S. Cl. CPC G01P 15/125; G01P 15/0802; B81B 2207/03; G01P 2015/0837; B81B 2201/0235; B81B 7/0087

(57) ABSTRACT

A sensor component. The sensor component includes a microelectromechanical z inertial sensor, including two sensor elements situated on a substrate and each designed in the form of a z rocker. The sensor elements each includes a seismic mass structure, elastically deflectable with respect to the substrate with the aid of a torsion spring, which has a heavy side and an oppositely situated light side with regard to the torsion springs. The seismic mass structure of the two sensor elements have different perforations on its heavy and/or light side(s), which effectuate a different sensitivity of the two sensor elements to a temperature gradient running in the z direction. The sensor component also includes an evaluation circuit designed to ascertain an acceleration in the z direction by evaluating the deflection of the seismic mass structure of the two sensor elements.

### CROSS REFERENCE

The present application claims the benefit under 35 U.S.C. § 119 of German Patent Application No. DE 102020211924.4 filed on Sep. 23, 2020, which is expressly incorporated herein by reference in its entirety.

### FIELD

The present invention relates to a sensor component including a microelectromechanical z inertial sensor, which enables a compensation of measuring errors caused by temperature gradients. The present invention further relates to a method for ascertaining an acceleration in the z direction with the aid of the microelectromechanical z inertial sensor.

### BACKGROUND INFORMATION

Microelectromechanical sensors (so-called MEMS sensors) are used to detect different physical variables, such as pressure, rotation rate or acceleration. Typical MEMS sensors are installed in systems on circuit boards, by which not only interactions exist between the MEMS sensors and the circuit board but also those between MEMS sensors and further components situated on the circuit board, for example microchips. In systems such as smartphones or motor vehicles, CPU chips are thus frequently installed in the vicinity of the MEMS sensors. A particularly close arrangement of the components is unavoidable, in particular in products in the so-called consumer market (e.g., smart watches), due to space limitations (small volume and limited lateral extension). Since CPU chips are generally operated with varying time utilization, the waste heat generated by a microchip of this type is also subjected to corresponding time variations. This results in temporally variable temperature gradients between the CPU chip and the adjacent components, for example a MEMS sensor.

The temporally variable temperature gradient is particularly striking in an acceleration sensor designed in the form of a z rocker. In this type of sensor, a temperature gradient perpendicular to the z rocker results in a varying expansion of the contained gas in the cavity above and below the z rocker. The varying expansion of the contained gas, in turn, results in a deflection of the z rocker and thus in a change in the capacitance of the measuring electrodes, which is erroneously interpreted as acceleration. The system thus generates an acceleration signal, even though no corresponding acceleration is present in the z direction.

### SUMMARY

One object of the present invention is to provide a possibility for providing the measuring accuracy of a microelectromechanical z inertial sensor in the presence of temporally varying temperature gradients. This object may be achieved with the aid of the particular subject matter of example embodiments of the present invention. Advantageous embodiments of the present invention are disclosed herein.

According to an example embodiment of the present invention, a sensor component including a microelectromechanical z inertial sensor is provided with two sensor elements, each designed in the form of a z rocker, situated on a substrate. The sensor elements each have a seismic mass structure, which is elastically deflectable with respect to the substrate with the aid of a torsion spring, and which has a heavy side and an oppositely situated light side with regard to the torsion spring. The seismic mass structures of the two sensor elements have different perforations on their heavy and/or light sides, which effectuate a different response characteristic of the two sensor elements with respect to a temperature gradient running in the z direction. The sensor component further includes an evaluation circuit, designed to ascertain an acceleration in the z direction by evaluating the deflection of the seismic mass structures of the two sensor elements. With the aid of a sensor component designed in this way, it is possible to detect the presence of vertical temperature gradients within the inertial sensor during the measurement of accelerations in the z direction. In this way, erroneous outputs of the acceleration sensor may be effectively avoided. In addition, an increased measuring accuracy as well as a better reliability of the relevant inertial sensor further result from the use of two sensor elements.

In one specific embodiment of the present invention, it is provided that the evaluation circuit is designed to determine a temperature gradient running in the z direction, based on a deviation of the deflections of the seismic mass structures of the two sensor elements and to use it to correct the ascertained acceleration in the z direction. With the aid of this measure, it is possible to quantitatively detect the influence of the vertical temperature gradient on the acceleration values. A correction of the measured acceleration may thus be carried out. In this way, the measuring accuracy of the inertial sensor may be significantly improved.

In a further specific embodiment of the present invention, it is provided that the different perforations of the relevant sides of the two seismic mass structures are due to holes having a different size, shape, number and/or arrangement. A multiplicity of variation possibilities is offered hereby, which permit a particularly optimal adaptation of the sensitivity of the relevant sensor element with respect to vertical temperature gradients and simultaneously ensure a sufficient undercutting of the seismic mass structures during the manufacturing process.

In a further specific embodiment of the present invention, it is provided that the seismic mass structure of the first sensor element has a perforation formed by holes having a shape deviating from a square on at least one side, while the seismic mass structure of the second sensor element has a perforation formed by square holes on the relevant side. With the aid of square holes, particularly good results may be obtained in the undercutting of the seismic mass structures.

In a further specific embodiment of the present invention, it is provided that the seismic mass structure of the second sensor element has a perforation formed by linear holes on the corresponding side.

In a further specific embodiment of the present invention, it is provided that the two sensor elements are provided with essentially the same design with regard to the mass and mass distribution of their seismic mass structures, the stiffness of their torsion springs and the arrangement of corresponding electrodes for the capacitive detection of their deflection, so that the two sensor elements have the same sensitivity in the z direction. If the two sensor elements have the same sensitivity to z accelerations and different sensitivities to vertical temperature gradients, the model for calculating a corrected acceleration value may be particularly simple.

In a further specific embodiment of the present invention, it is provided that the two sensor elements are situated in parallel to each other, so that the heavy sides of their seismic mass structures are situated on the same side of the torsion springs. In this arrangement, the two sensor elements may be particularly easily manufactured with the same sensitivity to z accelerations.

In a further specific embodiment of the present invention, it is provided that the two sensor elements are situated anti-parallel to each other, so that the heavy sides of their seismic mass structures are situated on opposite sides of the torsion springs. In this arrangement, temperature gradients occurring within a shared cavity may be reduced faster.

According to a further aspect of the present invention, a microelectromechanical z inertial sensor is also provided for the aforementioned sensor component. The advantages already mentioned in connection with the sensor component result for the microelectromechanical z inertial sensor.

Finally, according to a further aspect of the present invention, a method is provided for ascertaining an acceleration in the z direction with the aid of a microelectromechanical z inertial sensor, which includes two sensor elements designed in the form of a z rocker, each including a seismic mass, which is elastically deflectable with the aid of a torsion spring. The two sensor elements have an identical sensitivity to an acceleration in the z direction and a different sensitivity to a temperature gradient running in the z direction. The method includes a separate detection of the deflections of the seismic mass structures of the two sensor elements as well as an ascertainment of an acceleration in the z direction by evaluating the deflections of the seismic mass structures of the two sensor elements, a temperature gradient running in the z direction being ascertained, based on a deviation between the deflections of the seismic mass structures of the two sensor elements, and used to correct the ascertained acceleration in the z direction.

The present invention is described in greater detail below on the basis of the figures.

### BRIEF DESCRIPTION OF THE DRAWINGS

FIG. 1 schematically shows a cross-section of a z inertial sensor, which includes a rocker-shaped sensor element including a seismic mass structure elastically suspended with the aid of a torsion spring.

FIG. 2 schematically shows a top view of the rocker-shaped sensor element from FIG. 1.

FIG. 3 schematically shows a z inertial sensor, including two rocker-shaped sensor elements, which are situated in a cavity formed by a shared housing, the light side of the seismic mass structure of the first sensor element having a perforation in the form of linear holes, while the corresponding side of the seismic mass structure of the second sensor element has a perforation in the form of square holes, in accordance with an example embodiment of the present invention.

FIG. 4 shows a variation of the z inertial sensor from FIG. 3, in which the rocker-shaped sensor elements are, however, situated in two separate cavities formed by a partition wall of a shared housing, in accordance with an example embodiment of the present invention.

FIG. 5 shows a variation of the z inertial sensor from FIG. 3, in which the two rocker-shaped sensor elements are, however, situated anti-parallel to each other, in accordance with an example embodiment of the present invention.

FIG. 6 shows a variation of the z inertial sensor from FIG. 3, in which the different perforations are, however, formed at the light sides of the seismic mass structure of the two sensor elements, in accordance with an example embodiment of the present invention.

FIG. 7 shows a variation of the z inertial sensor from FIG. 3, in which the perforation of the heavy side of the seismic mass structure of the first sensor element is designed in the form of large square holes, in accordance with an example embodiment of the present invention.

FIG. 8 shows a variation of the z inertial sensor from FIG. 3, in which the seismic mass structure of the first sensor element is formed by circular holes on both sides, in accordance with an example embodiment of the present invention.

FIG. 9 schematically shows a structure of a sensor component, which includes a z inertial sensor and an evaluation circuit, in accordance with an example embodiment of the present invention.

### DETAILED DESCRIPTION OF EXAMPLE EMBODIMENTS

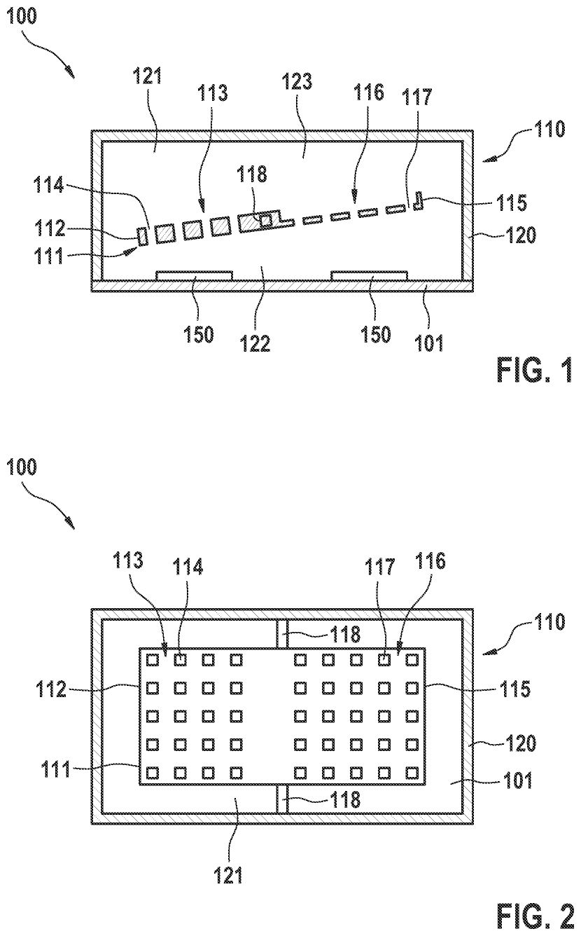

FIG. 1 shows a microelectromechanical z inertial sensor, including a rocker-shaped MEMS sensor element 110. Sensor element 110, which is situated in a cavity 121 delimited by substrate 101 and a cover-shaped sensor housing 120, includes a seismic mass structure 111, which is anchored on the substrate via one or multiple torsion springs 118 and which is generally created by structuring a function layer situated on a substrate 101. Seismic mass structure 111 has a heavy side 112 and an oppositely situated light side 115 with regard to torsion springs 118. Due to the asymmetrical mass structure distribution resulting therefrom, a deflection of the rocker is effectuated in the presence of an acceleration in the z direction. The deflection of seismic mass structure 111 may be measured capacitively, for example. For this purpose, two electrodes 150 are situated on substrate 101 in FIG. 1, whose electrical potential measurably changes upon a deflection of seismic mass structure 111, due to the capacitive interaction. Corresponding electrodes may also be situated in a different location, for example above seismic mass structure 111, to permit a differential evaluation.

As is further apparent from FIG. 1, seismic mass structure 111 has a perforation 113, 116 formed in each case from multiple holes 114, 117 on its two sides 112, 115. Holes 114, 117 designed in the form of continuous openings are used to remove the sacrificial layers during the gas phase etching to manufacture the microelectromechanical structures. As is apparent from the top view of rocker-shaped sensor element 110 shown in FIG. 2, holes 114, 117 are distributed in a preferably uniform grid over seismic mass 111 and have a square shape in the present example. Perforation 113 of heavy side 112 is made up of a slightly smaller number of holes 114. In principle, rocker-shaped sensor elements 110 of this type may also be installed in a shared cavity together with structures for detecting the x and y directions.

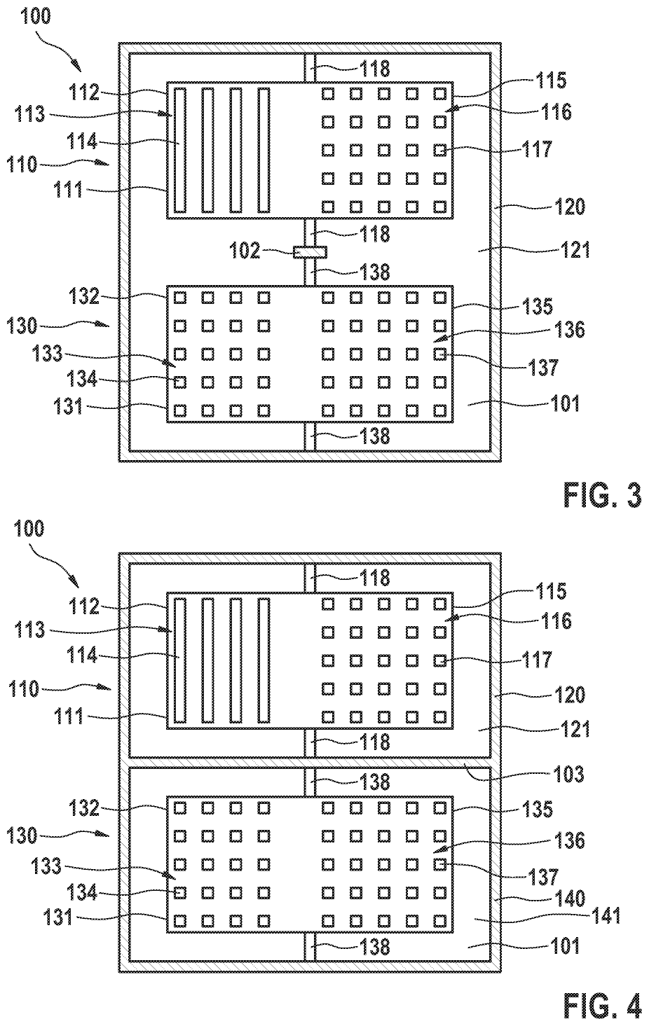

FIG. 3 shows the top view of a modified z inertial sensor 100, including two separately operated sensor elements 110, 130 accommodated in a cavity 121 formed by a shared housing 120. Similarly to the specific embodiment shown in FIG. 2, the two sensor elements 110, 130 designed in the form of a z rocker each include a seismic mass structure 111, 131 elastically suspended with respect to substrate 101 via torsion springs 118, 138 and each having a heavy side 112, 132 and an oppositely situated light side 115, 135 with regard to particular torsion springs 118, 138. In the present example, torsion springs 118, 138 are each connected to the outer wall of housing 120 and to a middle anchor structure 102. The two sensor elements 110, 130 are preferably designed with the same electrical sensitivity to an acceleration in the z direction. Since the electrical sensitivity is influenced, in particular, by the stiffness of the torsion springs, the mass of the z rocker, the distribution of this mass on the z rocker, and the distances of the electrodes from the z rocker, these factors are preferably designed to be the same for both sensor elements 110, 130.

In contrast to their electrical sensitivity, the two sensor elements 110, 130 have, however, different sensitivities to a vertical temperature gradient in cavity 121. To achieve this, the two sensor elements 110, 130 are equipped with differently shaped seismic mass structures 111, 131, the different shaping preferably being achieved by different perforations of at least one side of the two seismic mass structures 111, 131. A different geometry, size and/or number of holes 114, 134 in seismic masses 111, 131 thus typically result in a different response or sensitivity of the two sensor elements 110, 130 to vertical temperature gradients. Changes of the vertical temperature gradient are influenced, among other things, by openings 114, 117, 134, 137 in seismic mass structure 111, 131, which must be present for manufacturing reasons during the gas phase etching. The exact geometry (slit, square, rectangle, circle, ellipsis, etc.) and arrangement of these openings 114, 117, 134, 137 influence the intensity of the deflection of a z rocker in the presence of a vertical temperature gradient. The two sensor elements 110, 130 are therefore designed in such a way that holes 114, 117, 134, 137 on their seismic mass structures 111, 131 have different geometries. The influences of a vertical temperature gradient on the two z rockers 100, 130 are of different intensities. In the exemplary embodiment shown here, mass structures 111, 131 each have the same perforation 116, 136 on their light sides 115, 135 in the form of a matrix-shaped arrangement of square-shaped holes 117, 137. In contrast, heavy sides 112, 132 of the two mass structures 111, 131 each have different perforations 113, 133, heavy side 112 of first sensor element 110 having a total of four linear holes 114, while heavy side 132 of second sensor element 130 has a matrix-shaped arrangement of square holes 134.

A modified variant of z inertial sensor 100 from FIG. 3 is shown in FIG. 4, in which the two rocker-shaped sensor elements 110, 130 are each accommodated in a separate cavity 121, 141 according to the case shown in FIG. 2. Z inertial sensor 100 includes only one housing 120, 140, the two cavities 121, 141 being separated from each other by an internal partition wall 103. In principle, it is also possible to implement the two cavities 121, 141 with the aid of two separate housings 120, 140.

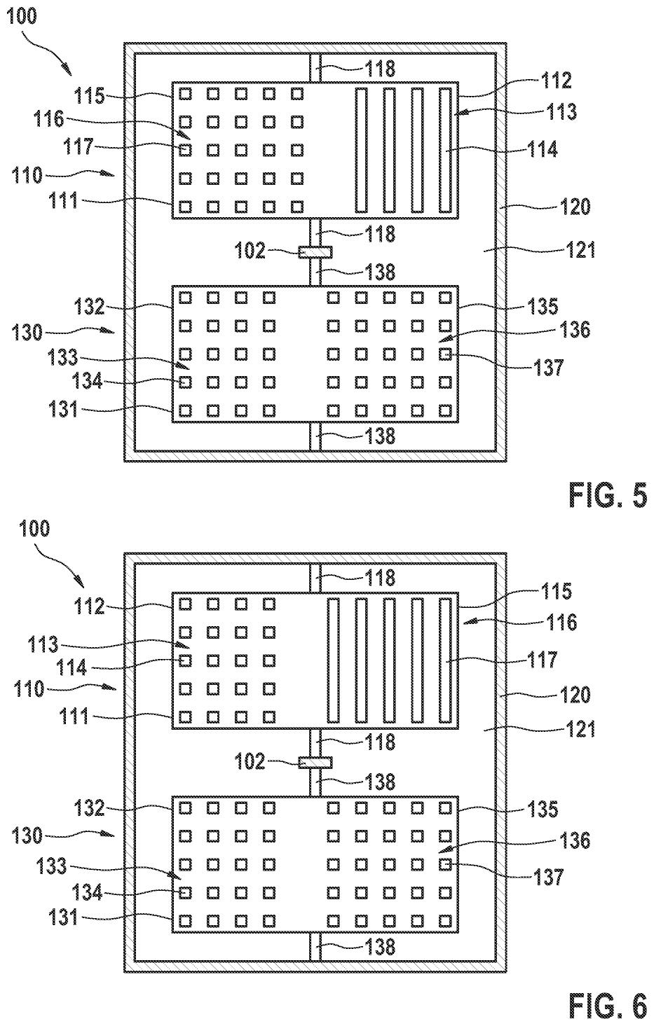

A further variant of z inertial sensor 100 shown in FIG. 3 is illustrated in FIG. 5, which has an anti-parallel arrangement of the two sensor elements 110, 130. First sensor element 110 is situated in a mirror-image manner with respect to torsion spring 118.

FIG. 6 shows a further variant of z inertial sensor 100 shown in FIG. 3. In contrast to the cases described above, different perforations 116, 136 are now situated on light sides 115, 135 of the two seismic mass structures 111, 131.

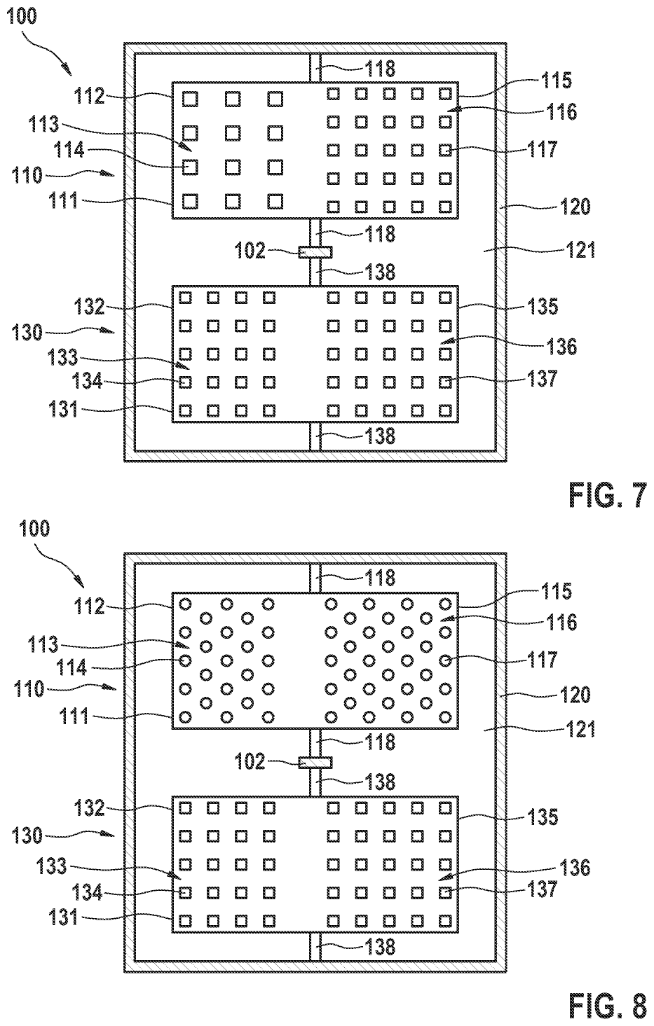

FIG. 7 shows a further variant of z inertial sensor 100 shown in FIG. 3. In the present case, heavy side 112 of first sensor element 110 has a perforation 113 including larger square holes 114.

FIG. 8 shows a further variant of z inertial sensor 100 illustrated in FIG. 3, in which first sensor element 110 has perforations 113, 116 formed by circular holes 114, 117 on both sides 112, 115. Holes 114, 117 also include a different distribution.

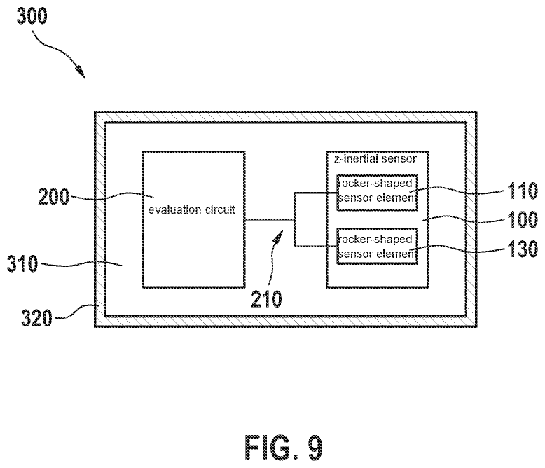

FIG. 9 shows a sensor component 300, including a z inertial sensor 100, which includes two rocker-shaped sensor elements 110, 130. Sensor component 300 further includes an evaluation circuit 200 (ASIC), with the aid of which an evaluation of the two rocker-shaped sensor elements 110, 130 takes place. Z inertial sensor 100 and evaluation circuit 200 may be situated on a shared substrate 310, as indicated here, and be surrounded by a shared housing 310. Evaluation circuit 200 is connected to z inertial sensor 100 or to sensor elements 110, 130 with the aid of suitable signal lines 210. Each sensor element 110, 130 is preferably evaluated separately. By a comparison of measuring signals of first sensor element 110 with the measuring signals of second sensor element 130, a decision takes place as to whether or the extent to which an actual acceleration or a vertical temperature gradient exists. If the signals of the two sensor elements 110, 130 correspond, it may be assumed that an actual acceleration exists. Conversely, if a deviation of the signals of the two sensor elements 110, 130 exists, it may be assumed that a vertical temperature gradient is present. The temperature gradient or its influence on the signals may be quantified, using suitable evaluation methods, and a correction of the measured z acceleration may be carried out, using this information. Alternatively, in the example illustrated in FIG. 9, each rocker-shaped sensor element 110, 130 may also be connected to a separate ASIC.

In an alternative design variant, instead of two sensor elements 110, 130 having the same electrical sensitivity to z accelerations, two sensor elements 110, 130 may also be used, which have different electrical sensitivities to z accelerations as well as different sensitivities to vertical temperature gradients. An evaluation of the signals and differentiation between a z acceleration and a vertical temperature gradient may be calculated in the particular evaluation circuit of the individual z rockers by stored tables, functions or models, which depict the sensitivity to a z acceleration and to a vertical temperature gradient. Two arbitrary rocker-shaped sensor elements may thus be used, whose signals are each conducted separately to an evaluation circuit (ASIC), the acceleration being calculated from the effect of a vertical temperature gradient with the aid of a suitable model. The model for the calculation is simpler, the smaller the difference of the electrical sensitivity and the greater the difference of the sensitivity to vertical temperature gradients of the two sensor elements is. For this reason, the z inertial sensor described in greater detail above, in which the two sensor elements 110, 130 have the same electrical sensitivity to z accelerations, is a particularly advantageous specific embodiment.

The perforation of the z rockers may be formed by different geometric shapes or different combinations of these geometric shapes (e.g., squares, rectangles, lines, circles, ellipses, polygons, etc.). The configuration with the aid of the different geometries of the perforation should, however, preferably take place in such a way that the electrical sensitivity between the two rocker-shaped sensor elements 110, 130 remains as uniform as possible, and different sensitivities to vertical temperature gradients are achieved at the same time.

Although the present invention was illustrated and described in greater detail by the preferred exemplary embodiments, the present invention is not limited by the described examples. Instead, other variations may be derived therefrom by those skilled in the art without departing from the scope of protection of the present invention.

What is claimed is:

1. A sensor component, comprising:
a microelectromechanical z inertial sensor, which includes two sensor elements situated on a substrate, each of the sensor elements being in the form of a z rocker, the sensor elements each include a seismic mass structure, elastically deflectable with respect to the substrate with the aid of a torsion spring, which has a heavy side and an oppositely situated light side with regard to the torsion spring, the seismic mass structure of the two sensor elements have different perforations on their heavy and/or light sides, which effectuate a different sensitivity of the two sensor elements to a temperature gradient running in a z direction; and
an evaluation circuit configured to ascertain an acceleration in the z direction by evaluating the deflection of the seismic mass structure of the two sensor elements.

2. The sensor component as recited in claim 1, wherein the evaluation circuit is configured to determine a temperature gradient running in the z direction, based on a deviation of the deflection of the seismic mass structure of the two sensor elements and to use the temperature gradient to correct the ascertained acceleration in the z direction.

3. The sensor component as recited in claim 1, wherein the different perforations their heavy and/or light sides of the two seismic mass structures are due to holes having a different size and/or different shape and/or different number and/or different arrangement.

4. The sensor component as recited claim 1, wherein the seismic mass structure of a first sensor element of the sensor elements has a perforation formed by holes having a shape deviating from the square on at least one side, while the seismic mass structure of a second sensor element of the sensor elements has a perforation formed by square holes on a side corresponding to the at least one side of the first sensor element.

5. The sensor component as recited in claim 4, wherein the seismic mass structure of the second sensor element has a perforation formed by linear holes on the corresponding side.

6. The sensor component as recited in claim 1, wherein the two sensor elements are provided with the same design with regard to mass and mass distribution of their seismic mass structures, a stiffness of their torsion springs and arrangement of corresponding electrodes for capacitive detection of a deflection, so that the two sensor elements have the same sensitivity to an acceleration in the z direction.

7. The sensor component as recited in claim 1, wherein the two sensor elements are situated in parallel to each other, so that the heavy sides of their seismic mass structures are each situated on the same side of the torsion springs.

8. The sensor component as recited in claim 1, wherein the two sensor elements are situated anti-parallel to each other, so that the heavy sides of their seismic mass structures are each situated on opposite sides of the torsion springs.

9. The sensor component as recited in claim 1, wherein the two sensor elements are situated in a shared cavity or are each situated in a separate cavity.

10. A microelectromechanical z inertial sensor for a microelectromechanical sensor component, the micromechanical z intertial sensor including two sensor elements situated on a substrate, each of the sensor elements being in the form of a z rocker, the sensor elements each include a seismic mass structure, elastically deflectable with respect to the substrate with the aid of a torsion spring, which has a heavy side and an oppositely situated light side with regard to the torsion spring, the seismic mass structure of the two sensor elements have different perforations on their heavy and/or light sides, which effectuate a different sensitivity of the two sensor elements to a temperature gradient running in a z direction.

11. A method for ascertaining an acceleration in a z direction using a microelectromechanical z inertial sensor, which includes two sensor elements which are each in the form of a z rocker, each of the sensor elements including a seismic mass structure which is elastically deflectable using a torsion spring, the two sensor elements having an identical sensitivity to an acceleration in a z direction and a different sensitivity to a temperature gradient running in the z direction, the method comprising the following steps:
separately detecting deflections of the seismic mass structures of the two sensor elements; and
ascertaining an acceleration in the z direction by evaluating the deflections of the seismic mass structures of the two sensor elements;
wherein a temperature gradient running in the z direction is ascertained, based on a deviation between the deflections of the seismic mass structures of the two sensor elements and is used to correct the ascertained acceleration in the z direction.
